(19) United States
(12) Patent Application Publication
(10) Pub. No.: US 2002/0158245 A1
(43) Pub. Date: Oct. 31, 2002

(54) Structure and method for fabricating semiconductor structures and devices utilizing binary metal oxide layers

(75) Inventors: Zhiyi Yu, Gilbert, AZ (US); Ravindranath Droopad, Chandler, AZ (US); William J. Ooms, Prescott, AZ (US)

Correspondence Address: MOTOROLA, INC., CORPORATE LAW DEPARTMENT - #56-238, 3102 NORTH 56TH STREET, PHOENIX, AZ, 85018, US

(73) Assignee: Motorola, Inc.

(21) Appl. No.: 09/842,734

(22) Filed: Apr. 26, 2001

(51) Int. Cl. H01L 29/12; H01L 21/16; H01L 31/0392; H01L 27/12

(52) U.S. Cl. 257/43; 438/85; 438/104; 438/754; 257/347; 257/352; 438/149

(57) ABSTRACT

High quality epitaxial layers of monocrystalline materials can be grown overlying monocrystalline substrates such as large silicon wafers by forming a compliant substrate for growing the monocrystalline layers. One way to achieve the formation of a complaint substrate includes first growing a monocrystalline binary metal oxide material layer (14) on a substrate (12). The binary metal oxide material layer (14) is lattice matched to both the underlying substrate (12) and the overlying monocrystalline material layer (16).

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include a high-quality monocrystalline material layer overlying binary oxides.

### BACKGROUND OF THE INVENTION

Semiconductor devices typically include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films, such as GaAs, on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of the monocrystalline material to be of low crystalline quality.

In an effort to achieve high crystalline quality in monocrystalline material layers, growing such layers on silicon substrates using a single transition layer formed of perovskite oxide, such as a SrTiO₃ layer, between the substrate and the monocrystalline material layer has been proposed. However, use of perovskite layers to grow overlying monocrystalline material layers poses several challenges. First, stoichiometric perovskite materials typically are semiconducting due to oxygen vacancies. In addition, the interface between the silicon substrate and the perovskite layer has a negligible conduction band offset such that the Schottky electron leakage current is intrinsically high. Second, due to its unit cell crystalline structure, perovskite poses step height mismatch problems when deposited on a substrate. When rotated 45° against the substrate lattice unit cell, the in-plane lattice mismatch between the growing perovskite layer and the substrate can be fairly small, e.g., 1.7% between strontium titanate and silicon. However, the 45° in-plane lattice unit cell rotation does not reduce the lattice mismatch along the growth (vertical) direction and a large step height mismatch at the step edges still exists which may cause defects during the initial nucleation and growth of the overlying monocrystalline film. Third, the perovskite surface may terminate in both Ti—O and Sr—O bonds. Termination with different oxide bonds hinders the growth of a subsequent high quality monocrystalline structure.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material, while exhibiting minimal leakage current.

Accordingly, a need exists for a semiconductor structure that provides a high quality monocrystalline film or layer over another stress-relieving layer and for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits having a grown monocrystalline film the same crystal orientation as an underlying substrate. This monocrystalline material layer may be comprised of a semiconductor material, a compound semiconductor material, and other types of material such as metals and non-metals.

In addition, a need exists for a semiconductor structure having a high quality monocrystalline material layer and which exhibits low electron leakage current.

A further need exists for a semiconductor structure that utilizes a transition layer formed of binary metal oxide material overlying a monocrystalline substrate for the formation of quality semiconductor structures, devices and integrated circuits.

### BRIEF DESCRIPTION OF THE DRAWINGS

The present invention is illustrated by way of example and not limitation in the accompanying figures, in which like references indicate similar elements, and in which:

FIGS. 1-3 illustrate schematically, in cross-section, device structures in accordance with exemplary embodiments of the invention;

FIG. 4 illustrates graphically the relationship between maximum attainable film thickness and lattice mismatch between a host crystal and a grown crystalline overlayer;

FIGS. 5A-5D illustrate schematically, in cross section, the formation of a device structure in accordance with another embodiment of the invention; and

FIGS. 6A-6C illustrates schematically, in cross section, the formation of yet another embodiment of a device structure in accordance with the invention.

Skilled artisans will appreciate the elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE INVENTION

FIG. 1 illustrates schematically, in cross section, a portion of a semiconductor structure 10 in accordance with an embodiment of the invention. Semiconductor structure 10 includes a monocrystalline substrate 12, a binary metal oxide material layer 14, and a monocrystalline material layer 16. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 10 also includes an amorphous intermediate layer 18 positioned between substrate 12 and binary metal oxide layer 14. Structure 10 may also include a template layer 20 between the binary metal oxide layer 14 and monocrystalline material layer 16. As will be explained more fully below, the template layer helps to initiate the growth of the monocrystalline material layer on the binary metal oxide layer. The amorphous intermediate layer 18 helps to relieve the strain in the binary metal oxide layer and by doing so, aids in the growth of a high crystalline quality binary metal oxide layer.

Substrate 12, in accordance with an embodiment of the invention, is a monocrystalline semiconductor or compound semiconductor wafer, preferably of large diameter. The wafer can be of, for example, a material from Group IV of the periodic table, and preferably a material from Group IVB. Examples of Group IV semiconductor materials include silicon, germanium, mixed silicon and germanium, mixed silicon and carbon, mixed silicon, germanium and carbon, and the like. Preferably substrate 12 is a wafer containing silicon or germanium, and most preferably is a high quality monocrystalline silicon wafer as used in the semiconductor industry. Substrate 12 may optionally include a plurality of material layers such that the composite substrate may be tailored to the quality, performance, and manufacturing requirements of a variety of semiconductor device applications.

In another embodiment of the invention, substrate 12 may comprise a (001) Group IV material that has been off-cut towards a (110) direction. The growth of materials on a miscut Si (001) substrate is known in the art. For example, U.S. Pat. No. 6,039,803, issued to Fitzgerald et al. on Mar. 21, 2000, which patent is herein incorporated by reference, is directed to growth of silicon-germanium and germanium layers on miscut Si (001) substrates. Substrate 12 may be off-cut in the range of from about 2 degrees to about 6 degrees towards the (110) direction. A miscut Group IV substrate reduces dislocations and results in improved quality of subsequently grown layer 16.

Binary metal oxide layer 14 is preferably formed of an alkaline earth metal oxide (of the general form AₘOₙ, where A is an alkaline earth metal) and is selected for its crystalline compatibility with the underlying substrate and with the overlying monocrystalline material layer. Materials that are suitable for the binary metal oxide layer include, but are not limited to, barium oxide (BaO), strontium oxide (SrO), magnesium oxide (MgO), calcium oxide (CaO), zirconium oxide (ZrO₂), cerium oxide (CeO₂), praseodymium oxide (PrO₂) and yttria-stabilized zirconia (YSZ). Preferably, binary metal oxide layer 14 is formed of BaO or a mixture of BaO and SrO. Alternatively, the binary metal oxide layer 14 may comprise an oxide of a blend of any alkaline earth metal oxides (of the general form AxByOz, where A and B are alkaline earth metals), such as (Ba,Sr)O. Binary metal oxide layer 14 may have a thickness in the range of from about 2 to 100 nm. Because of its crystalline structure, binary metal oxide layer 14 may form a relatively flat surface when epitaxially grown on substrate 12 as compared to perovskite materials and, accordingly, does not present the step height mismatch problems that perovskite materials present. In addition, rotation of the orientation of binary metal oxide layer 14 on substrate 12 is not required to achieve substantial matching of the crystal lattice constants of layer 14 and substrate 12, as is required for perovskite deposition on substrate 12. Binary metal oxide layer 14 may also provide an advantage for FET applications, as it is a better insulator than a perovskite oxide layer. In addition, binary metal oxide layer 14 may serve as a better diffusion barrier than a perovskite oxide layer.

In accordance with another embodiment of the invention, amorphous intermediate layer 18 is grown on substrate 12 at the interface between substrate 12 and growing binary metal oxide layer 14 by the oxidation of substrate 12 during the growth of layer 14. The amorphous intermediate layer serves to relieve strain that might otherwise occur in the monocrystalline binary metal oxide layer as a result of differences in the lattice constants of the substrate and the binary metal oxide layer. As used herein, lattice constant refers to the distance between atoms of a unit cell measured in the plane of the surface. If such strain is not relieved by the amorphous intermediate layer, the strain relaxation may cause defects in the crystalline structure of the binary metal oxide layer. Defects in the crystalline structure of the binary metal oxide layer, in turn, would make it difficult to achieve a high quality crystalline structure in monocrystalline material layer 16 which may comprise a semiconductor material, a compound semiconductor material, or another type of material such as a metal or a non-metal.

The material for monocrystalline material layer 16 can be selected as desired for a particular structure or application. For example, the monocrystalline material of layer 16 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), lead selenide (PbSe), lead telluride (PbTe), lead sulfide selenide (PbSSe) and the like. However, monocrystalline material layer 16 may also comprise other semiconductor materials, metals, oxides, or non-metal materials which are used in the formation of semiconductor structures, devices and/or integrated circuits.

Appropriate materials for template 20 are discussed below. Suitable template materials chemically bond to the surface of the binary metal oxide layer 14 at selected sites and provide sites for the nucleation of the epitaxial growth of monocrystalline material layer 16. When used, template layer 20 has a thickness ranging from about 1 to about 10 monolayers.

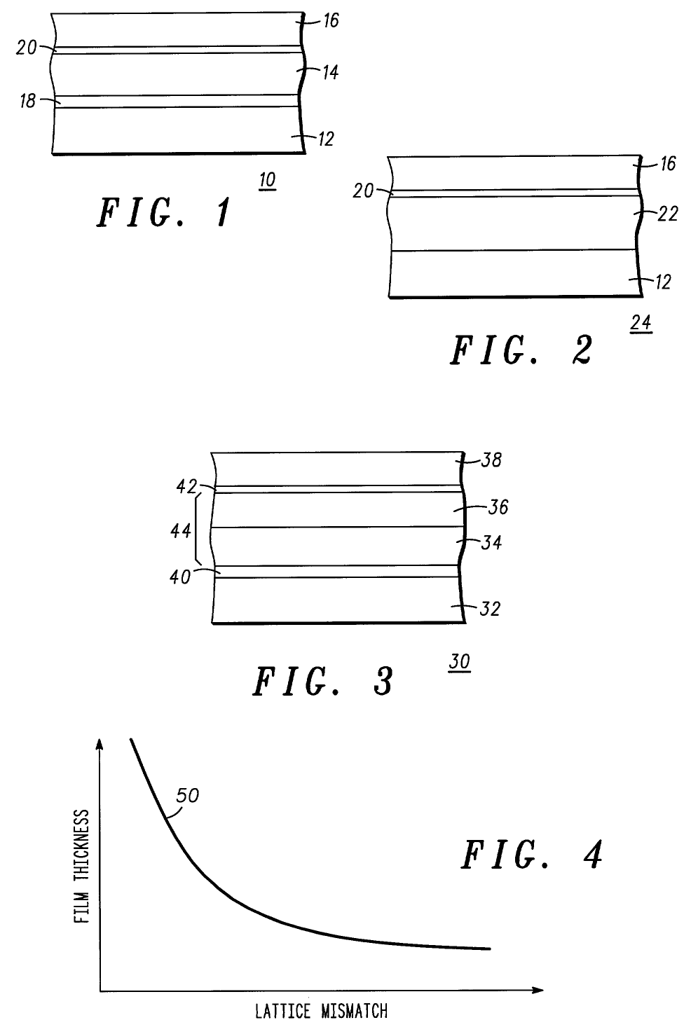

FIG. 2 schematically illustrates, in cross section, a portion of a semiconductor structure 24 in accordance with another exemplary embodiment of the invention. Structure 24 is similar to structure 10, except that structure 24 includes an amorphous layer 22, rather than binary metal oxide layer 14 and amorphous interface layer 18.

Amorphous layer 22 may be formed by first forming a binary metal oxide layer and an amorphous intermediate layer in a similar manner to that described above. Monocrystalline material layer 16 is then formed (by epitaxial growth) overlying the monocrystalline binary metal oxide layer 14. The binary metal oxide layer is then exposed to an anneal process to convert the monocrystalline binary metal oxide layer to an amorphous layer. Amorphous layer 22 formed in this manner comprises materials from both the binary metal oxide layer and the intermediate layer, which amorphous layers may or may not amalgamate. Thus, layer 22 may comprise one or two amorphous layers. Formation of amorphous layer 22 between substrate 12 and monocrystalline material layer 16 relieves stresses between layers 12 and 16 and provides a true complaint substrate for subsequent processing. For example, before annealing, a high-quality thin film of monocrystalline material layer 16 may be epitaxially grown over binary metal oxide layer 14. After annealing, monocrystalline material layer 16 may continue to be epitaxially grown to a thickness suitable for a desired application. In this manner, strain due to lattice mismatch between layers 16 and 14 may be relieved, resulting in high-quality monocrystalline material layer 16 grown to a desired thickness. Binary metal oxide layer 14 provides an advantage when used to form amorphous layer 22 as compared to a perovskite oxide layer as binary metal oxides require fewer steps and lower temperatures for amorphization than perovskite oxide materials.

FIG. 3 illustrates, in cross-section, a portion of a semiconductor structure 30 in accordance with a further embodiment of the invention. Structure 30 includes a monocrystalline substrate 32, a strained binary metal oxide stack 44 overlying substrate 32, and monocrystalline material layer 38 epitaxially grown overlying strained binary metal oxide stack 44. Binary metal oxide stack includes a first binary metal oxide layer 34 epitaxially grown overlying substrate 32 and a second binary metal oxide layer 36 epitaxially grown overlying first binary metal oxide layer 34. In another exemplary embodiment, structure 30 may have amorphous intermediate layer 40 formed between first binary metal oxide layer 34 and substrate 32. In yet a further embodiment, structure 30 may include template layer 42 formed between second binary metal oxide layer 36 and monocrystalline material layer 38. Substrate 32 may be formed of the same materials as described above for substrate 12 with reference to FIGS. 1 and 2, but is preferably formed of silicon. Monocrystalline material layer 38 may be formed of the same materials as described above for monocrystalline material layer 16. In addition, amorphous intermediate layer 40 may be formed of the same materials as described above for amorphous intermediate layer 18 and template layer 42 may be formed of the same materials as described for template layer 20.

First binary metal oxide layer 34 may be formed of any of the materials described above for binary metal oxide layer 14 and may have a thickness in the range of about 1-10 nm. Second binary metal oxide layer 36 may also be formed of any of the materials described above for binary metal oxide layer 14 and having a lattice constant different from the lattice constant of first binary metal oxide layer 34. Second binary metal oxide layer 36 may have a thickness in the range of about 1-10 nm. With different lattice constants between the first and second binary metal oxide layers, strain results between and within the layers, at the interface between substrate 32 and first binary metal oxide layer 34, and/or at the interface between second binary metal oxide layer 36 and monocrystalline material layer 38. For example, if monocrystalline material layer 38 is formed of gallium arsenide (GaAs), first binary metal oxide layer 34 may be formed of BaO, and second binary metal oxide layer 36 may be formed of SrO. GaAs has a lattice constant of 5.633 angstroms and BaO has a lattice constant of 5.542 angstroms; accordingly, BaO is closely lattice matched to GaAs. Because SrO has a lattice constant of 5.160 angstroms, which is different from the lattice constant of BaO, a strained binary metal oxide stack is created. This strain aids in localizing, bending or deflecting defects within the binary metal oxide layers, aiding in the growth of a high quality monocrystalline material layer 38.

While strained binary metal oxide stack 44 is illustrated in FIG. 3 having two binary metal oxide layers, it will be understood that stack 44 may have any number of binary metal oxide layers that is suitable for a desired application.

The following non-limiting, illustrative examples illustrate various combinations of materials useful in structures 10, 24 and 30 in accordance with various alternative embodiments of the invention. These examples are merely illustrative, and it is not intended that the invention be limited to these illustrative examples.

### EXAMPLE 1

This example 1 is an exemplary embodiment of structure 10 illustrated in FIG. 1. Monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, binary metal oxide layer 14 is a monocrystalline layer of BaO and the amorphous intermediate layer 18 is a layer of silicon oxide (SiOₓ) formed at the interface between the silicon substrate and the binary metal oxide layer. The binary metal oxide layer can have a thickness in the range of about 2-5 nm. The amorphous intermediate layer of silicon oxide can have a thickness of about 0.5-5 nm, and preferably a thickness of about 1 to 2 nm.

In accordance with this embodiment of the invention, monocrystalline material layer 16 is a compound semiconductor layer of GaAs or aluminum gallium arsenide (AlGaAs) having a thickness of about 1 nm to about 100 micrometers and preferably a thickness of about 0.5 micrometers to 10 micrometers. The thickness generally depends on the application for which the layer is being prepared. To facilitate the epitaxial growth of GaAs or AlGaAs on the monocrystalline oxide, a template layer is formed by capping the binary metal oxide layer. The template layer is preferably 1-10 monolayers of Ba—As, Ba—O—As, Ba—Ga—O, or Ba—Al—O.

### EXAMPLE 2

This embodiment of the invention is an example of structure 24 illustrated in FIG. 2. Substrate 12, template layer 20 and monocrystalline material layer 16 may be the same as those described above in connection with example 1.

Amorphous layer 22 is an amorphous oxide layer which is suitably formed of a combination of amorphous intermediate layer materials (e.g., layer 18 materials as described above) and binary metal oxide layer materials (e.g., layer 14 materials as described above). For example, amorphous layer 22 may include a combination of SiOₓ and BaO, which combine or mix, at least partially, during an anneal process to form amorphous oxide layer 22.

The thickness of amorphous layer 22 may vary from application to application and may depend on such factors as desired insulating properties of layer 22, type of monocrystalline material comprising layer 16, and the like. In accordance with one exemplary aspect of the present embodiment, layer 22 thickness is about 2 nm to about 100 nm, preferably about 2-10 nm, and more preferably about 5-6 nm.

### EXAMPLE 3

This embodiment of the invention is an example of structure 30 illustrated in FIG. 3. Monocrystalline substrate 32 may be a silicon substrate oriented in the (100) direction. Template layer 42 may be formed of any of the materials described for template layer 20. Monocrystalline material layer 38 may be formed of GaAs. In addition, a strained stack 44 is formed between substrate 32 and monocrystalline material layer 38. In one embodiment, strained stack 44 is formed between amorphous intermediate layer 40 and template layer 42. Strained stack 44 has a first binary metal oxide layer 34 and a second binary metal oxide layer 36. First binary metal oxide layer 34 may be formed of BaO, which has a lattice constant closely matched to the overlying GaAs layer. Second binary metal oxide layer 36 may be formed of SrO, which has a lattice constant that is different from first binary metal oxide layer. With the difference in lattice constants between the first and second binary metal oxide layers, strain may be effected within and/or between the first and second binary metal oxide layers, at the interface of the second binary metal oxide layer and the monocrystalline material layer, and/or at the interface of the first binary metal oxide layer and the substrate. This strain serves to attract defects to the binary metal oxide layers, permitting the growing of a high-quality monocrystalline material layer 38. Amorphous intermediate layer 40 is a layer of SiOₓ formed at the interface between the silicon substrate and the BaO binary metal oxide layer. Amorphous intermediate layer 40 may serve to compromise the lattice mismatch between the silicon substrate and the BaO layer.

FIG. 4 illustrates graphically the relationship of the achievable thickness of a grown crystal layer of high crystalline quality as a function of the mismatch between the lattice constants of the host crystal and the grown crystal. Curve 50 illustrates the boundary of high crystalline quality material. The area to the right of curve 50 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

The following example illustrates a process, in accordance with one embodiment of the invention, for fabricating a semiconductor structure such as the structure depicted in FIG. 1. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, offcut about 2°-6° off axis towards the (110) direction. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface may exhibit an ordered 2×1 structure. If an ordered 2×1 structure has not been achieved at this stage of the process, the structure may be exposed to additional strontium until an ordered 2×1 structure is obtained. The ordered structure forms a template for the ordered growth of an overlying layer of a monocrystalline oxide. This template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-300° C. and a layer of barium oxide (BaO) is epitaxially grown on the substrate by molecular beam epitaxy (MBE). The MBE process is initiated by purging the MBE apparatus with oxygen and opening shutters in the apparatus to expose a barium source. After initiating growth of the barium oxide, the partial pressure of oxygen is increased above the initial minimum value. The overpressure of oxygen causes the growth of an amorphous silicon oxide layer at the interface between the underlying substrate and the growing barium oxide layer. The growth of the silicon oxide layer results from the diffusion of oxygen through the growing barium oxide layer to the interface where the oxygen reacts with silicon at the surface of the underlying substrate. Strain that otherwise might exist in the barium oxide layer because of the small mismatch in lattice constant between the silicon substrate and the growing crystal is relieved by the amorphous silicon oxide intermediate layer. The barium oxide grows as an ordered monocrystal without the need to rotate its crystalline orientation with respect to the ordered crystalline structure of the underlying substrate.

After the barium oxide layer has been grown to the desired thickness, the monocrystalline barium oxide is capped by a template layer that is conducive to the subsequent growth of an epitaxial layer of a desired monocrystalline material. For example, for the subsequent growth of a monocrystalline compound semiconductor material layer of GaAs, the MBE growth of the barium oxide monocrystalline layer can be capped by terminating the growth with 1-2 monolayers of barium. Following the formation of this capping layer, arsenic is deposited to form a Ba—As bond or a Ba—O—As bond. Either of these form an appropriate template for deposition and formation of gallium arsenide monocrystalline layer. Following the formation of the template, gallium is subsequently introduced to the reaction with the arsenic and GaAs forms. Alternatively, gallium can be deposited on the capping layer to form a Ba—O—Ga bond, and arsenic is subsequently introduced with the gallium to form the GaAs layer. Because barium oxide reacts easily with moisture and carbon dioxide to form hydroxides and carbonates, it is desirable to limit exposure of the barium oxide layer to ambient atmosphere before deposition of the GaAs layer.

Structure 24, illustrated in FIG. 2, may be formed by growing a binary metal oxide layer, forming an amorphous oxide layer over substrate 12, and growing thin layer of monocrystalline material over the binary metal oxide layer, as described above. The binary metal oxide layer and the amorphous oxide layer may then be exposed to an anneal process sufficient to change the crystalline structure of the binary metal oxide layer from monocrystalline to amorphous, thereby forming an amorphous layer such that the combination of the amorphous oxide layer and the now amorphous binary metal oxide layer form a single amorphous oxide layer 22. The monocrystalline material layer then may be further grown to a thickness suitable for a desired application.

In accordance with one aspect of this embodiment, layer 22 is formed by exposing substrate 12, the binary metal oxide layer, the amorphous oxide layer, and the monocrystalline material layer to a rapid thermal anneal process with a peak temperature of about 700° C. to about 1000° C. and a process time of about 5 seconds to about 10 minutes. However, other suitable anneal processes may be employed to convert the binary metal oxide layer to an amorphous layer in accordance with the present invention. For example, laser annealing, electron beam annealing, or “conventional” thermal annealing processes (in the proper environment) may be used to form layer 22.

The process described above illustrates a process for forming a semiconductor structure having a silicon substrate, a binary metal oxide layer and a monocrystalline material layer comprising GaAs by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline material layers comprising other III-V and II-VI monocrystalline compound semiconductors, semiconductors, metals and non-metals can be deposited overlying the monocrystalline binary metal oxide layer.

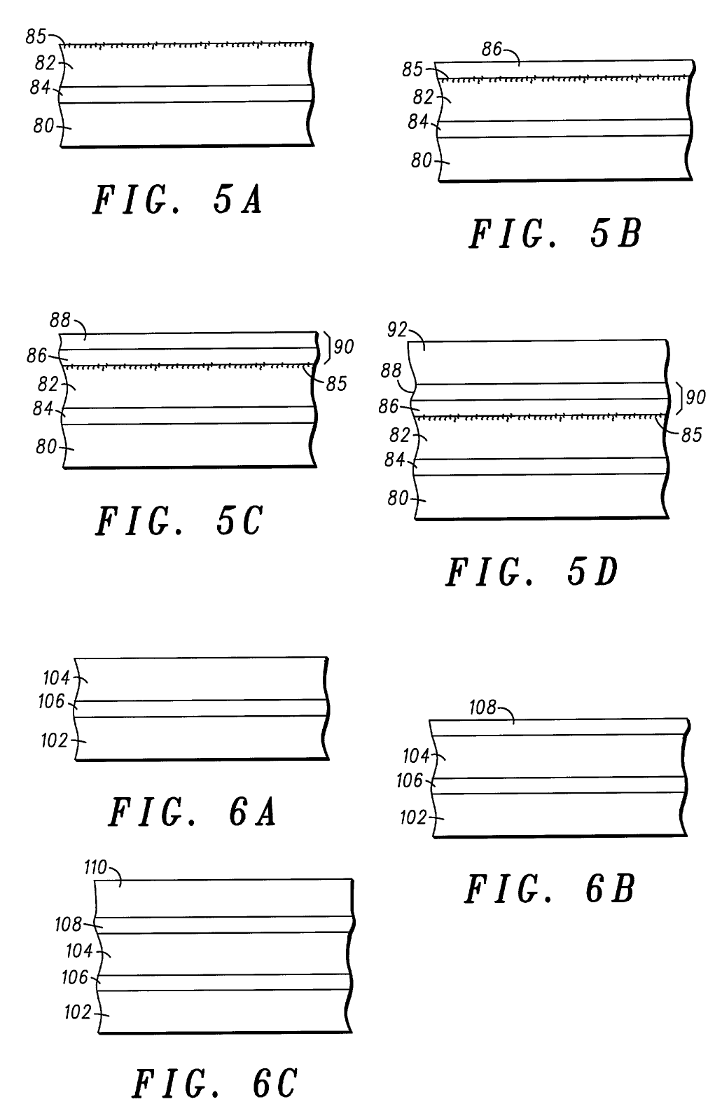

The formation of a device structure in accordance with another embodiment of the invention is illustrated schematically in cross-section in FIGS. 5A-5D. Like the previously described embodiments referred to in FIGS. 1-3, this embodiment of the invention involves the process of forming a complaint substrate utilizing the epitaxial growth of single crystal oxides, such as the formation of binary metal oxide layer as previously described with reference to FIGS. 1 and 3 and amorphous layer 22 previously described with reference to FIG. 2, and the formation of a template layer. However, the embodiment illustrated in FIGS. 5A-5D utilizes a template that includes a surfactant to facilitate layer-by-layer monocrystalline material growth.

Turning now to FIG. 5A, an amorphous intermediate layer 84 is grown on substrate 80 at the interface between substrate 80 and a growing monocrystalline binary metal oxide layer 82 by the oxidation of substrate 80 during the growth of layer 82. Layer 82 may comprise any of those materials previously described with reference to layer 14 in FIG. 1 and any of those compounds previously described with reference to layer 22 in FIG. 2 which is formed from layers 14 and 18 referenced in FIG. 1.

Layer 82 is grown with a strontium (Sr) terminated surface represented in FIG. 5A by hatched line 85 which is followed by the addition of a template layer 90 which includes a surfactant layer 86 and capping layer 88 as illustrated in FIGS. 5B and 5C. Surfactant layer 86 may comprise, but is not limited to, elements such as Al, In, Bi and Ga, but will be dependent upon the composition of layer 82 and the overlying layer of monocrystalline material for optimal results. In one exemplary embodiment, aluminum (Al) is used for surfactant layer 86 and functions to modify the surface and surface energy of layer 82. Preferably, surfactant layer 86 is epitaxially grown, to a thickness of one to two monolayers, over layer 82 as illustrated in FIG. 5B by way of MBE, although other epitaxial processes may also be performed including CVD, MOCVD, MEE, ALE, PVD, CSD, PLD, or the like.

Surfactant layer 86 is then exposed to a Group V element, arsenic for example, to form capping layer 88 as illustrated in FIG. 5C. Surfactant layer 86 may be exposed to a number of materials to create capping layer 88 such as elements which include, but are not limited to, As, P, Sb and N. Surfactant layer 86 and capping layer 88 combine to form template layer 90.

Monocrystalline material layer 92, which in this example is a compound semiconductor such as GaAs, is then deposited via MBE, CVD, MOCVD, MEE, ALE, PBD, CSD, PLD, and the like to form the final structure illustrated in FIG. 5D.

FIGS. 6A-6C schematically illustrate, in cross-section, the formation of another embodiment of a device structure in accordance with the invention. This embodiment includes a compliant layer that functions as a transition layer that uses calthrate or Zintl-type bonding. More specifically, this embodiment utilizes an intermetallic template layer to reduce the surface energy of the interface between material layers thereby allowing for two-dimensional layer by layer growth.

The structure illustrated in FIG. 6A includes a monocrystalline substrate 102, an amorphous intermediate layer 106 and a binary metal oxide layer 104. Amorphous intermediate layer 106 is grown on substrate 102 at the interface between substrate 102 and binary metal oxide layer 104 as previously described with reference to FIG. 1. Binary metal oxide layer 104 may comprise any of those materials previously described with reference to binary metal oxide layer 14 in FIG. 1. In an exemplary embodiment, layer 104 may be formed of BaO. Substrate 102 is preferably silicon but may also comprise any of those materials previously described with reference to substrate 12 in FIGS. 1 and 2.

A template layer 108 is deposited over binary metal oxide layer 104 as illustrated in FIG. 6B and preferably comprises a thin layer of Zintl-type phase material composed of metals and metalloids having a great deal of ionic character. As in previously described embodiments, template layer 108 is deposited by way of MBE, CVD, MOCVD, MEE, ALE, PVD, CSD, PLD, or the like to achieve a thickness of one monolayer. Template layer 108 functions as a “soft” layer with non-directional bonding but high crystallinity which absorbs stress build up between layers having lattice mismatch. Material for template 108 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂.

A monocrystalline material layer 110 is epitaxially grown over template layer 108 to achieve the final structure illustrated in FIG. 6C. As a specific example, an SrAl₂ layer may be used as template layer 108 and an appropriate monocrystalline material layer 110 such as a compound semiconductor material GaAs is grown over the SrAl₂. The Al—Ba (from the binary metal oxide layer of BaO) bond is mostly metallic while the Al—As (from the GaAs layer) bond is weakly covalent. The Ba participates in two distinct types of bonding with part of its electric charge going to the oxygen atoms in the lower binary metal oxide layer 104 comprising BaO to participate in ionic bonding and the other part of its valence charge being donated to Al in a way that is typically carried out with Zintl phase materials. The amount of the charge transfer depends on the relative electronegativity of elements comprising the template layer 108 as well as on the interatomic distance. In this example, Al assumes an sp³ hybridization and can readily form bonds with monocrystalline material layer 110, which in this example, comprises compound semiconductor material GaAs.

The compliant substrate produced by use of the Zintl-type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming high quality monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters. By use of this type of substrate, a relatively inexpensive “handle” wafer overcomes the fragile nature of compound semiconductor and other monocrystalline material layers by placing them over a relatively more durable and easy to fabricate base material. In addition, this “handle” wafer serves to reduce defect density in the monocrystalline material layer and reduces leakage current from the substrate to the monocrystalline material layer.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of the present invention.

Benefits, other advantages, and solutions to problems have been described above with regard to specific embodiments. However, the benefits, advantages, solutions to problems, and any element(s) that may cause any benefit, advantage, solution to occur or become more pronounced are not to be constructed as critical, required, or essential features or elements of any or all of the claims. As used, herein, the terms “comprises,” “comprising” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure comprising:
a monocrystalline substrate;
an amorphous intermediate layer formed overlying said substrate;
a binary metal oxide material layer formed overlying said amorphous intermediate layer; and
a monocrystalline material layer formed overlying said binary metal oxide material layer.

2. The semiconductor structure of claim 1, wherein said binary metal oxide material layer is formed of a binary material oxide material having a rock-salt crystalline structure.

3. The semiconductor structure of claim 1, further comprising a template layer formed overlying said binary metal oxide material layer and underlying said monocrystalline material layer.

4. The semiconductor structure of claim 1, wherein said substrate comprises silicon.

5. The semiconductor structure of claim 1, wherein said substrate comprises a (001) semiconductor material having an orientation from about 2 degrees to about 6 degrees offset toward the (110) direction.

6. The semiconductor structure of claim 1, wherein said binary metal oxide material layer is formed of at least one of: BaO, SrO, MgO, CaO, ZrO2, CeO2, PrO2, YSZ and an oxide blend comprising at least two of Ba, Sr, Mg, Ca, Zr, Ce, and Pr.

7. The semiconductor structure of claim 1, wherein said monocrystalline material layer comprises at least one of a semiconductor material, a compound semiconductor material, a metal, an oxide, and a non-metal.

8. The semiconductor structure of claim 3, wherein said template layer comprises a Zintl-type phase material.

9. The semiconductor structure of claim 8, wherein said Zintl-type phase material comprises at least one of SrAl₂, (MgCaYb)Ga₂, (Ca,Sr,Eu,Yb)In₂, BaGe₂As, and SrSn₂As₂.

10. The semiconductor structure of claim 3, wherein said template layer comprises a surfactant material.

11. The semiconductor structure of claim 10, wherein said surfactant material comprises at least one of Al, In, Bi, and Ga.

12. The semiconductor structure of claim 10, wherein said template layer further comprises a capping layer.

13. The semiconductor structure of claim 12, wherein said capping layer is formed by exposing said surfactant material to a cap-inducing material.

14. The semiconductor structure of claim 13, wherein said cap-inducing material comprises at least one of As, P, Sb and N.

15. The semiconductor structure of claim 1, wherein the binary metal oxide material layer comprises a binary metal oxide material formed as a monocrystalline binary metal oxide and subsequently heat treated to convert the monocrystalline binary metal oxide to an amorphous binary metal oxide.

16. The semiconductor structure of claim 1, wherein said monocrystalline substrate is characterized by a first lattice constant, said monocrystalline material layer is characterized by a second lattice constant that is different from said first lattice constant, and said binary metal oxide material layer is characterized by a third lattice constant that is different from said first and said second lattice constant.

17. The semiconductor structure of claim 2, wherein said substrate comprises silicon and said amorphous intermediate layer comprises a silicon oxide.

18. A semiconductor structure comprising:
a monocrystalline substrate;
a strained stack overlying said substrate, said strained stack comprising:
a first binary metal oxide material layer; and
a second binary metal oxide material layer overlying said first binary metal oxide material layer; and
a monocrystalline material layer formed overlying said strained stack.

19. The semiconductor structure of claim 18, further comprising an amorphous intermediate layer formed overlying said substrate and underlying said strained stack.

20. The semiconductor structure of claim 18, further comprising a template layer formed overlying said strained stack and underlying said monocrystalline material layer.

21. The semiconductor structure of claim 18, wherein said substrate comprises silicon.

22. The semiconductor structure of claim 18, wherein said substrate comprises a (001) semiconductor material having an orientation from about 2 degrees to about 6 degrees offset toward the (110) direction.

23. The semiconductor structure of claim 18, wherein said first binary metal oxide material layer is formed of at least one of BaO, SrO, MgO, CaO, ZrO₂, CeO₂, PrO2, YSZ and an oxide blend comprising at least two of Ba, Sr, Mg, Ca, Zr, Ce, and Pr, and wherein said first binary metal oxide material layer has a first lattice constant.

24. The semiconductor structure of claim 23, wherein said second binary metal oxide material layer is formed of at least one of BaO, SrO, MgO, CaO, ZrO₂, CeO₂, PrO2, YSZ and an oxide blend comprising at least two of Ba, Sr, Mg, Ca, Zr, Ce, and Pr, and wherein said second binary metal oxide material layer has a second lattice constant that is different from said first lattice constant.

25. The semiconductor structure of claim 18, wherein said monocrystalline material layer comprises at least one of a semiconductor material, a compound semiconductor material, a metal, an oxide, and a non-metal.

26. The semiconductor structure of claim 20, wherein said template layer comprises a Zintl-type phase material.

27. The semiconductor structure of claim 26, wherein said Zintl-type phase material comprises at least one of SrAl₂, (MgCaYb)Ga₂, (Ca,Sr,Eu,Yb)In₂, BaGe₂As, and SrSn₂As₂.

28. The semiconductor structure of claim 20, wherein said template layer comprises a surfactant material.

29. The semiconductor structure of claim 28, wherein said surfactant material comprises at least one of Al, In, Bi, and Ga.

30. The semiconductor structure of claim 28, wherein said template layer further comprises a capping layer.

31. The semiconductor structure of claim 30, wherein said capping layer is formed by exposing said surfactant material to a cap-inducing material.

32. The semiconductor structure of claim 31, wherein said cap-inducing material comprises at least one of As, P, Sb and N.

33. The semiconductor structure of claim 18, wherein said monocrystalline substrate is characterized by a first lattice constant, said monocrystalline material layer is characterized by a second lattice constant that is different from said first lattice constant, said first binary metal oxide material layer is characterized by a third lattice constant that is different from said first and said second lattice constants, and said second binary metal oxide material layer is characterized by fourth lattice constant that is different from said first and said third lattice constants.

34. The semiconductor structure of claim 33, wherein said first binary metal oxide material layer comprises BaO and said second binary metal oxide material layer comprises SrO.

35. The semiconductor structure of claim 19, wherein said substrate comprises silicon and said amorphous intermediate layer comprises a silicon oxide.

36. The semiconductor structure of claim 18, wherein said strained stack further comprises a third binary metal oxide layer.

37. The semiconductor structure of claim 18, wherein said first binary metal oxide material layer is formed of a binary metal oxide material having a rock-salt crystalline configuration.

38. The semiconductor structure of claim 18, wherein said second binary metal oxide material layer is formed of a binary metal oxide material having a rock-salt crystalline configuration.

39. A process for fabricating a semiconductor device structure comprising:
providing a monocrystalline substrate;
forming an amorphous intermediate layer overlying said substrate;
epitaxially growing a first monocrystalline binary metal oxide material layer overlying said amorphous intermediate layer, wherein said first monocrystalline binary metal oxide material layer has a first lattice constant; and
epitaxially growing a monocrystalline material layer overlying said binary metal oxide material layer.

40. The process of claim 39, further comprising forming a template layer between said first binary metal oxide material layer and said monocrystalline material layer.

41. The process of claim 39, further comprising heat treating said first monocrystalline binary metal oxide material layer to convert said first monocrystalline binary metal oxide material layer to an amorphous binary metal oxide material layer.

42. The process of claim 39, further comprising epitaxially growing a second monocrystalline binary metal oxide material layer overlying said first monocrystalline binary metal oxide material layer, wherein said second monocrystalline binary metal oxide material layer has a second lattice constant that is different from said first lattice constant.

43. The process of claim 39, wherein said epitaxially growing a first binary metal oxide material layer comprises epitaxially growing a first binary metal oxide material layer of at least one of BaO, SrO, MgO, CaO, ZrO₂, CeO₂, PrO2, YSZ and an oxide blend comprising at least two of Ba, Sr, Mg, Ca, Zr, Ce, and Pr.

44. The process of claim 42, wherein said epitaxially growing said second binary metal oxide material layer comprises epitaxially growing said second binary metal oxide material layer of at least one of BaO, SrO, MgO, CaO, ZrO₂, CeO₂, PrO2, YSZ and an oxide blend comprising at least two of Ba, Sr, Mg, Ca, Zr, Ce, and Pr.

45. The process of claim 42, wherein said monocrystalline material layer comprises GaAs, said first monocrystalline binary metal oxide material layer comprises BaO, and said second monocrystalline binary metal oxide material layer comprises SrO.

46. The process of claim 39, wherein said epitaxially growing a first monocrystalline binary metal oxide material layer comprises epitaxially growing a first monocrystalline binary metal oxide material layer formed of a material having a rock-salt crystalline configuration.

47. The process of claim 42, wherein said epitaxially growing a second monocrystalline binary metal oxide material layer comprises growing a second monocrystalline binary metal oxide material layer formed of a material having a rock-salt crystalline configuration.

48. The process of claim 40, wherein said forming a template layer comprises forming a template layer of Zintl-type material.

49. The process of claim 48, wherein said forming a template layer comprises forming a template layer of at least one of SrAl₂, (MgCaYb)Ga₂, (Ca,Sr,Eu,Yb)In₂, BaGe₂As, and SrSn₂As₂.

50. The process of claim 40, wherein said forming a template layer comprises forming a template layer of a surfactant material.

51. The process of claim 50, wherein said forming a template layer comprising a surfactant material comprises forming a template layer of at least one of Al, In, Bi and Ga.

52. The process of claim 50, wherein said forming a template layer further comprises forming a capping layer.

53. The process of claim 52, wherein said forming a capping layer comprises forming a capping layer by exposing said surfactant material to a cap-inducing material.

54. The process of claim 53, wherein said exposing comprises exposing said surfactant material to at least one of As, P, Sb and N.
